(19) United States
(12) Patent Application Publication
(10) Pub. No.: US 2025/0029843 A1
(43) Pub. Date: Jan. 23, 2025

(54) SUBSTRATE-PROCESSING METHOD AND SUBSTRATE-PROCESSING APPARATUS

(71) Applicant: Tokyo Electron Limited, Tokyo (JP)

(72) Inventors: Hiroto FUJIKAWA, Yamanashi (JP); Tuhin Shuvra Basu, Yamanashi (JP)

(21) Appl. No.: 18/764,779

(22) Filed: Jul. 5, 2024

(30) Foreign Application Priority Data
Jul. 18, 2023 (JP) 2023-116908

(51) Int. Cl. H01L 21/311; H01L 21/324; H01L 21/67

(52) U.S. Cl. CPC H01L 21/31116; H01L 21/324; H01L 21/67069

(57) ABSTRACT

A substrate-processing method includes (a) providing a substrate including a silicon oxide film on a surface of the substrate; (b) supplying a first gas to the surface of the substrate, the first gas containing a hydrogen fluoride gas and containing no basic gas; and (c) after (b), supplying a second gas to the surface of the substrate, the second gas containing both a hydrogen fluoride gas and a basic gas.

### CROSS-REFERENCE TO RELATED APPLICATIONS

This application is based upon and claims priority to Japanese Patent Application No. 2023-116908, filed on Jul. 18, 2023, the entire contents of which are incorporated herein by reference.

### BACKGROUND

### 1. Field of the Invention

The present disclosure relates to substrate-processing methods and substrate-processing apparatuses.

### 2. Description of the Related Art

A technique of etching a silicon oxide film using a gas mixture of a hydrogen fluoride gas and an ammonia gas is known. See, for example, Japanese Patent Application Publication No. 2004-343094.

### SUMMARY

A substrate-processing method according to an aspect of the present disclosure includes: (a) providing a substrate including a silicon oxide film on a surface of the substrate; (b) supplying a first gas to the surface of the substrate, the first gas containing a hydrogen fluoride gas and containing no basic gas; and (c) after (b), supplying a second gas to the surface of the substrate, the second gas containing both a hydrogen fluoride gas and a basic gas.

### BRIEF DESCRIPTION OF THE DRAWINGS

FIG. 1 is a flowchart illustrating a substrate-processing method according to an embodiment;

FIG. 2 is a cross-sectional view illustrating an example of a substrate;

FIG. 3 is a view illustrating a surface reaction when a HF supply step is performed before a COR step;

FIG. 4 is a view illustrating a surface reaction when no HF supply step is performed before the COR step;

FIG. 5 is a cross-sectional view illustrating a substrate-processing apparatus according to an embodiment;

FIG. 6 is a graph indicating results obtained by measuring an in-plane distribution of an etching depth of a silicon oxide film; and

FIG. 7 is a graph indicating results obtained by measuring an in-plane distribution of an etching depth of a silicon nitride film.

### DETAILED DESCRIPTION OF THE INVENTION

The present disclosure provides a technique of being able to adjust an in-plane distribution of an etching depth.

Hereinafter, non-limiting embodiments of the present disclosure will be described with reference to the drawings. In the drawings, the same or corresponding members or components are designated by the same reference symbols, and duplicate description thereof will be omitted.

### [Etching of Silicon Oxide Film]

A technique of etching a silicon oxide film formed on the surface of a substrate through chemical oxide removal (COR) is known. In the COR, a gas mixture of a hydrogen fluoride (HF) gas and an ammonia (NH₃) gas is supplied to the silicon oxide film, thereby etching the silicon oxide film.

Etching of the silicon oxide film through COR is a highly reactive process. Therefore, when a gas mixture of a hydrogen fluoride gas and an ammonia gas is supplied from the outer periphery of the substrate along the surface of the substrate, the resulting etching depth of the silicon oxide film at the outer periphery of the substrate becomes larger than the resulting etching depth of the silicon oxide film at the center of the substrate, and in-plane uniformity in the etching depth may be lowered. This is likely because the hydrogen fluoride gas and the ammonia gas are consumed through reaction with the silicon oxide film at the outer periphery of the substrate before reaching the center of the substrate.

When the duration of the COR is extended, gradually, the center of the substrate is more likely to be etched than is the outer periphery of the substrate, and the in-plane uniformity is improved. However, when the duration of etching is extended, the etching depth of the silicon oxide film is increased. Therefore, it is challenging to improve the in-plane uniformity in the etching depth of the silicon oxide film through a short-term etching process (i.e., the etching depth to be achieved is small).

When a silicon nitride film serving as a hard mask is formed on the surface of the substrate, it is desired that the silicon nitride film is not etched or the silicon nitride film is not significantly etched upon etching of the silicon oxide film. However, when the duration of the COR is extended, the silicon nitride film is more likely to be etched.

The present inventors have found that the in-plane distribution in the etching depth of the silicon oxide film can be adjusted through a short-term etching process by supplying a first gas to the surface of the substrate before performing the COR, the first gas containing a hydrogen fluoride gas and containing no basic gas. Hereinafter, a substrate-processing method and a substrate-processing apparatus according to the embodiment will be described.

### [Substrate-Processing Method]

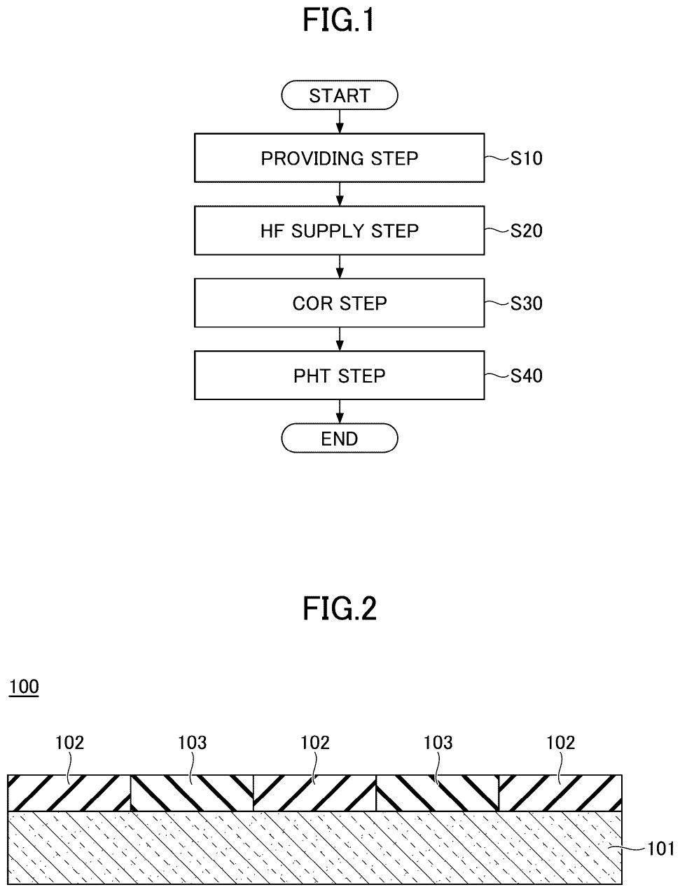

The substrate-processing method according to the embodiment will be described with reference to FIGS. 1 and 2. FIG. 1 is a flowchart illustrating the substrate-processing method according to the embodiment. FIG. 2 is a cross-sectional view illustrating an example of a substrate 100.

As illustrated in FIG. 1, the substrate-processing method according to the embodiment includes providing step S10, HF supply step S20, COR step S30, and PHT step S40.

Providing step S10 includes providing the substrate 100 including a silicon nitride film 102 and a silicon oxide film 103 on a surface thereof, as illustrated in FIG. 2. The silicon nitride film 102 and the silicon oxide film 103 are formed on an underlying substrate 101. The underlying substrate 101 is, for example, a silicon wafer. The silicon oxide film 103 is, for example, a thermal oxide film formed through thermal oxidation. Providing step S10 may include adjusting the temperature of the substrate 100 to a predetermined temperature, and maintaining the substrate 100 at the predetermined temperature. The predetermined temperature may be the same as a first process temperature as described below. In this case, there is no need to change the temperature when the flow proceeds to HF supply step S20 from providing step S10. As a result, productivity is improved.

HF supply step S20 is performed after providing step S10. HF supply step S20 includes supplying the first gas, containing the hydrogen fluoride gas and containing no basic gas, to the surface of the substrate 100. When the hydrogen fluoride gas is supplied to the surface of the substrate 100, the silicon oxide film 103 reacts with the hydrogen fluoride gas, thereby forming silicon tetrafluoride (SiF₄). When a native oxide film is present on the silicon nitride film 102, the native oxide film reacts with the hydrogen fluoride gas and is etched. The first gas may further include an inert gas, such as a nitrogen (Ne) gas. The first gas is, for example, a gas mixture of the hydrogen fluoride gas and the nitrogen gas. HF supply step S20 may include adjusting the temperature of the substrate 100 to the first process temperature, and maintaining the substrate 100 at the first process temperature. The first process temperature is the same as, for example, a second process temperature as described below.

COR step S30 is performed after HF supply step S20. COR step S30 includes modifying at least the surface layer of the silicon oxide film 103 into a reaction product through the COR, which performs etching chemically without generating plasma. COR step S30 includes supplying a second gas to the surface of the substrate 100, the second gas containing both a hydrogen fluoride gas and a basic gas. When the hydrogen fluoride gas and the basic gas are supplied to the surface of the substrate 100, the silicon oxide film 103 reacts with the hydrogen fluoride gas and the basic gas, thereby forming ammonium silicofluoride [(NH₄)₂SiF₆]. The basic gas is, for example, an ammonia gas. The basic gas may be a hydrazine (N₂H₄) gas. The second gas may further contain an inert gas, such as a nitrogen gas or the like. The second gas is, for example, a gas mixture of a hydrogen fluoride gas, an ammonia gas, and a nitrogen gas.

COR step S30 may be performed successively after HF supply step S20 in a state in which the supply of the hydrogen fluoride gas is continued. In other words, COR step S30 may be performed without a purge step after HF supply step S20. In this case, COR step S30 can be performed without removing the silicon tetrafluoride, formed on the surface of the substrate 100 in HF supply step S20, from the surface of the substrate 100.

COR step S30 may include maintaining the temperature of the substrate 100 at the second process temperature. The second process temperature may be, for example, 0° C. (degrees Celsius) or higher, and may be higher than room temperature. The second process temperature may be 120° C. or lower, and may be 80° C. or lower. When the second process temperature is 120° C. or lower, the silicon oxide film 103 is more likely to be etched.

The duration of HF supply step S20 may be longer than the duration of COR step S30. In this case, silicon tetrafluoride is more likely to be formed on the entire surface of the substrate 100. The duration of HF supply step S20 is, for example, 20 minutes. The duration of COR step S30 is, for example, 60 seconds.

PHT step S40 is performed after COR step S30. PHT step S40 includes sublimating the reaction product through post heat treatment (PHT) in which the substrate 100 is heat-treated in a state of being maintained at a third process temperature that is higher than the second process temperature. By performing PHT step S40, the reaction product remaining on the surface of the substrate 100 can be removed. PHT step S40 may include supplying a third gas to the surface of the substrate 100. The third gas is, for example, a hydrogen (H₂) gas.

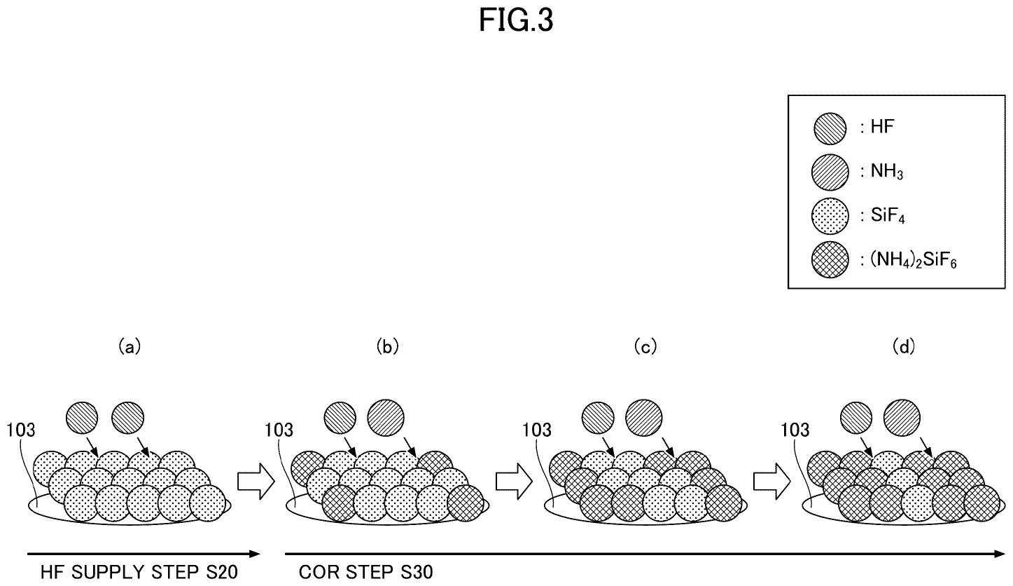

The surface reactions in the case of performing HF supply step S20 and COR step S30 in this order will be described with reference to FIG. 3. FIG. 3 is a view illustrating the surface reaction when HF supply step S20 is performed before COR step S30.

As illustrated in (a) of FIG. 3, when the hydrogen fluoride gas is supplied to the surface of the substrate 100 in HF supply step S20, the silicon oxide film 103 reacts with the hydrogen fluoride gas, thereby forming silicon tetrafluoride. The chemical reaction formula at this time is as follows.

SiO₂+4HF→SiF₄+2H₂O (1)

Subsequently, when a hydrogen fluoride gas and an ammonia gas are supplied to the surface of the substrate 100 in COR step S30, the silicon oxide film 103 reacts with the hydrogen fluoride gas and the ammonia gas, thereby forming silicon tetrafluoride. The chemical reaction formula at this time is as follows.

SiO₂+4HF+4NH₃→SiF₄+2H₂O+4NH₃ (2)

In COR step S30, ammonium silicofluoride [(NH₄)₂SiF₆] is formed through reaction of the silicon tetrafluoride formed in HF supply step S20 with the hydrogen fluoride gas and the ammonia gas. The chemical reaction formula at this time is as follows.

SiF₄+2HF+2NH₃→(NH₄)₂SiF₆ (3)

When COR step S30 is performed in a state in which the silicon tetrafluoride is present on the surface of the substrate 100, the reaction represented by chemical reaction formula (3) is more likely to proceed than does the reaction represented by chemical reaction formula (2). Therefore, when the hydrogen fluoride gas and the ammonia gas are supplied to the surface of the substrate 100, the ammonium silicofluoride is more likely to be formed through reaction of the silicon tetrafluoride with the hydrogen fluoride gas and the ammonia gas.

As illustrated in (b) of FIG. 3, when the hydrogen fluoride gas and the ammonia gas are supplied from the outer periphery of the substrate 100 along the surface of the substrate 100, the ammonium silicofluoride is formed through reaction of the silicon tetrafluoride at the outer periphery of the substrate 100 with the hydrogen fluoride gas and the ammonia gas immediately after the start of the supply thereof. This is likely because the reaction represented by chemical reaction formula (3) is highly reactive, and the hydrogen fluoride gas and the ammonia gas are consumed through reaction with the silicon tetrafluoride at the outer periphery of the substrate 100 before reaching the center of the substrate 100.

The ammonium silicofluoride suppresses formation of the silicon tetrafluoride through reaction of the silicon oxide film 103 with the hydrogen fluoride gas and the ammonia gas. As a result, etching of the silicon oxide film 103 is suppressed by the ammonium silicofluoride at the outer periphery of the substrate 100. Thereby, the etching rate of the silicon oxide film 103 at the center of the substrate 100 becomes larger than the etching rate of the silicon oxide film 103 at the outer periphery of the substrate 100. Thus, in the resulting in-plane distribution, the etching depth of the silicon oxide film 103 at the center of the substrate 100 is larger than the etching depth of the silicon oxide film 103 at the outer periphery of the substrate 100. That is, the in-plane profile of the etching depth becomes convex.

When the supply of the hydrogen fluoride gas and the ammonia gas to the substrate 100 is continued, as illustrated in (c) and (d) of FIG. 3, the region in which the ammonium silicofluoride is formed expands from the outer periphery to the center of the substrate 100. Therefore, the etching rate of the silicon oxide film 103 at the center of the substrate 100 becomes closer to the etching rate of the silicon oxide film 103 at the outer periphery of the substrate 100.

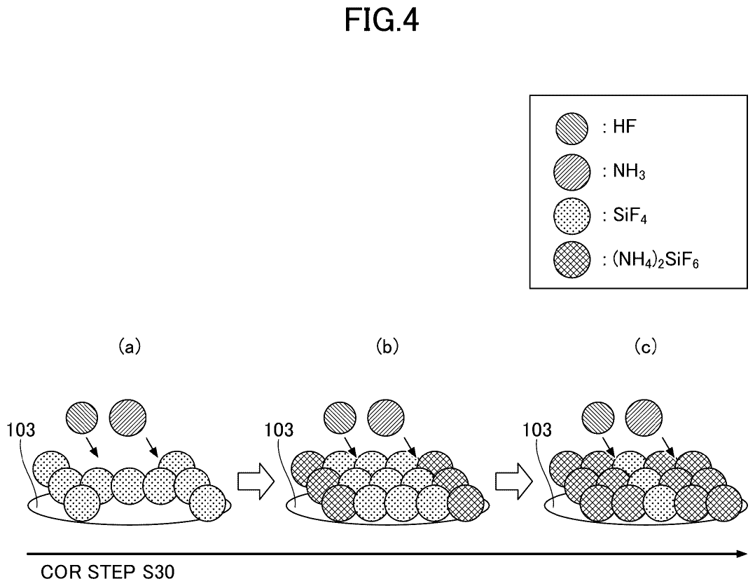

The surface reaction in the case of performing COR step S30 without performing HF supply step S20 will be described with reference to FIG. 4. FIG. 4 is a view illustrating the surface reaction when HF supply step S20 is not performed before COR step S30.

In the case of performing COR step S30 without performing HF supply step S20, when the hydrogen fluoride gas and the ammonia gas are supplied to the surface of the substrate 100 in COR step S30, the silicon oxide film 103 reacts with the hydrogen fluoride gas and the ammonia gas, thereby forming silicon tetrafluoride. The chemical reaction formula at this time is the same as chemical reaction formula (2) as described above.

As illustrated in (a) of FIG. 4, when the hydrogen fluoride gas and the ammonia gas are supplied from the outer periphery of the substrate 100 along the surface of the substrate 100, the silicon oxide film 103 is etched more at the outer periphery of the substrate 100 than at the center of the substrate 100 immediately after the start of the supply thereof. This is likely because the reaction represented by chemical reaction formula (2) is highly reactive, and the hydrogen fluoride gas and the ammonia gas are consumed through reaction with the silicon oxide film 103 at the outer periphery of the substrate 100 before reaching the center of the substrate 100. Thus, in the resulting in-plane distribution, the etching depth of the silicon oxide film 103 is larger at the outer periphery of the substrate 100 than at the center of the substrate 100. That is, the in-plane profile of the etching depth becomes concave.

When the supply of the hydrogen fluoride gas and the ammonia gas to the substrate 100 is continued, ammonium silicofluoride starts to be formed in the outer periphery of the substrate 100 as illustrated in (b) of FIG. 4. Further, when the supply of the hydrogen fluoride gas and the ammonia gas to the substrate 100 is continued, the region in which the ammonium silicofluoride is formed expands from the outer periphery of the substrate 100 to the center of the substrate 100 as illustrated in (c) of FIG. 4. Thereby, the etching rate of the silicon oxide film 103 at the center of the substrate 100 becomes larger than the etching rate of the silicon oxide film 103 at the outer periphery of the substrate 100. Thus, the in-plane distribution in which the etching depth of the silicon oxide film 103 is larger at the outer periphery of the substrate 100 than at the center of the substrate 100 is changing to an in-plane distribution in which the etching depth of the silicon oxide film 103 is larger at the center of the substrate 100 than at the outer periphery of the substrate 100. That is, the in-plane profile of the etching depth is changing from the concave profile to a convex profile.

In this manner, in the case of performing COR step S30 without performing HF supply step S20, the duration of etching becomes longer for adjusting the in-plane profile of the etching depth to a convex shape. Therefore, it is challenging to adjust the in-plane profile of the etching depth of the silicon oxide film 103 from a concave profile to a convex profile for a duration of etching shorter than the duration of etching that achieves a desired etching depth. When the silicon nitride film 102 serving as a hard mask is formed on the surface of the substrate 100, the silicon nitride film 102 is more likely to be etched as the duration of etching is extended, and etching selectivity of the silicon oxide film 103 relative to the silicon nitride film 102 is reduced.

As described above, according to the substrate-processing method according to the embodiment, HF supply step S20 is performed before COR step S30. Thereby, the in-plane distribution of the etching depth of the silicon oxide film 103 can be adjusted through a short-term etching process.

### [Substrate-Processing Apparatus]

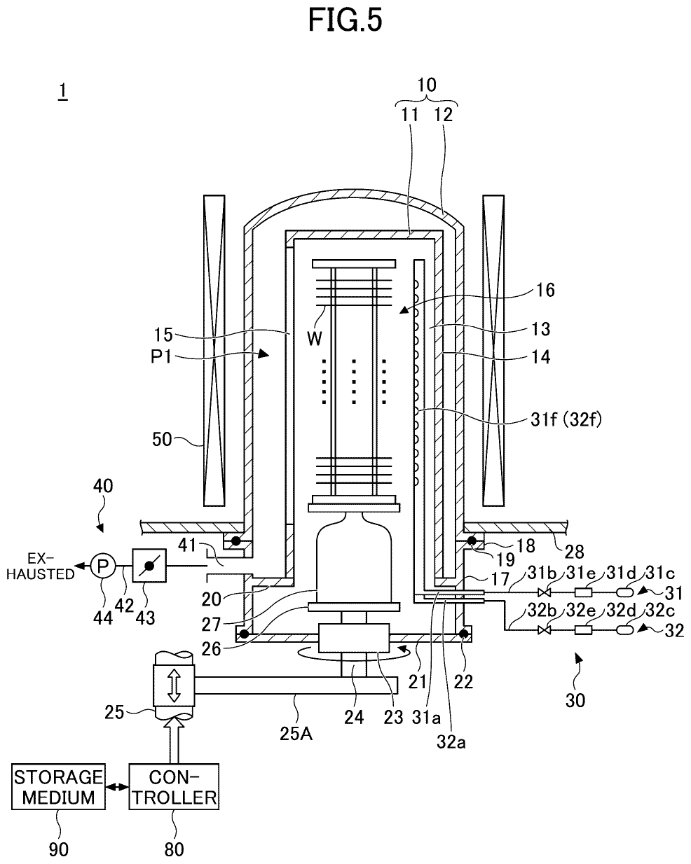

A substrate-processing apparatus 1 according to an embodiment will be described with reference to FIG. 5. As illustrated in FIG. 5, the substrate-processing apparatus 1 is a batch-type apparatus configured to perform processing of a plurality of substrates W at once.

The substrate-processing apparatus 1 includes a process chamber 10, a gas supply 30, an exhauster 40, a heater 50, and a controller 80.

The internal pressure of the process chamber 10 can be reduced. The process chamber 10 is configured to house substrates W. The process chamber 10 includes an inner tube 11 and an outer tube 12. The inner tube 11 and the outer tube 12 have a cylindrical shape with a ceiling and is opened at the bottom end thereof. The inner tube 11 and the outer tube 12 form a dual-tube structure in which the inner tube 11 and the outer tube 12 are disposed coaxially. The inner tube 11 and the outer tube 12 are formed of a heat-resistant material, such as quartz or the like.

The ceiling of the inner tube 11 may be, for example, flat. On one side of an inner side wall of the inner tube 11, a housing 13 configured to house gas nozzles is formed along a longitudinal direction (up-and-down direction) of the inner tube 11. For example, the side wall of the inner tube 11 is partially projected outward to form a projection 14, and the inner space of the projection 14 is formed as the housing 13.

In the opposite side wall of the inner tube 11, a rectangular opening 15 is formed to face the housing 13 along the longitudinal direction (up-and-down direction) of the inner tube 11.

The opening 15 is a gas exhaustion port that is formed such that a gas in the inner tube 11 can be exhausted therethrough. The opening 15 is formed such that the length of the opening 15 is the same as the length of a boat 16 or such that the opening 15 extends in the up-and-down direction so as to have a length longer than that of the boat 16.

The bottom end of the process chamber 10 is supported by a cylindrical manifold 17. The manifold 17 is formed of, for example, stainless steel. At the top end of the manifold 17, a flange 18 is formed. The flange 18 supports the bottom end of the outer tube 12. Between the flange 18 and the bottom end of the outer tube 12, a seal member 19, such as an O-ring or the like, is provided. Thereby, the inner space of the outer tube 12 is hermetically maintained.

The inner wall of an upper portion of the manifold 17 is provided with an annular support 20. The support 20 supports the bottom end of the inner tube 11. To the opening at the bottom end of the manifold 17, a cover 21 is hermetically attached via a seal member 22, such as an O-ring or the like. Thereby, the opening at the bottom end of the process chamber 10, i.e., the opening of the manifold 17 is hermetically sealed. The cover 21 is formed of, for example, stainless steel.

At the center of the cover 21, a penetrating rotating shaft 24 is provided via a magnetic fluid seal 23. The lower portion of the rotating shaft 24 is rotatably supported by an arm 25A of a raising and lowering mechanism 25 formed of a boat elevator.

At the top end of the rotating shaft 24, a rotating plate 26 is provided. On the rotating plate 26, the boat 16 retaining the substrates W is placed via a warming stage 27 formed of quartz. The boat 16 is rotated by rotating the rotating shaft 24. By raising or lowering the raising and lowering mechanism 25, the boat 16 moves upward and downward together with the cover 21. Thereby, the boat 16 is inserted into or released from the process chamber 10. The boat 16 can be housed in the process chamber 10. The boat 16 retains a plurality of (e.g., from 50 through 150) substrates W approximately in parallel at intervals in the up-and-down direction.

The gas supply 30 is configured to introduce various process gases used for the above-described substrate-processing method into the inner tube 11. The gas supply 30 includes a hydrogen fluoride supply 31 and an ammonia supply 32.

The hydrogen fluoride supply 31 includes: a hydrogen fluoride supply tube 31a in the process chamber 10; and a hydrogen fluoride supply path 31b external of the process chamber 10. The hydrogen fluoride supply path 31b sequentially includes a hydrogen fluoride supply source 31c, a mass flow controller 31d, and a valve 31e from upstream to downstream of a gas flow direction. Thereby, a hydrogen fluoride gas of the hydrogen fluoride supply source 31c is controlled by the valve 31e in terms of supply timing, and is also adjusted by the mass flow controller 31d to a predetermined flow rate. The hydrogen fluoride gas flows into the hydrogen fluoride supply tube 31a through the hydrogen fluoride supply path 31b, and is discharged from the hydrogen fluoride supply tube 31a into the process chamber 10.

The ammonia supply 32 includes: an ammonia supply tube 32a in the process chamber 10; and an ammonia supply path 32b external of the process chamber 10. The ammonia supply path 32b sequentially includes an ammonia source 32c, a mass flow controller 32d, and a valve 32e from upstream to downstream of a gas flow direction. Thereby, an ammonia gas of the ammonia source 32c is controlled by the valve 32e in terms of supply timing, and is also adjusted by the mass flow controller 32d to a predetermined flow rate. The ammonia gas flows into the ammonia supply tube 32a through the ammonia supply path 32b, and is discharged from the ammonia supply tube 32a into the process chamber 10.

The gas supply tubes (the hydrogen fluoride supply tube 31a and the ammonia supply tube 32a) are fixed to the manifold 17. The gas supply tubes are formed of, for example, quartz. The gas supply tubes each extend in the form of a straight line along a vertical direction at a position near the inner tube 11, and bend in an L shape to horizontally extend in the manifold 17, thereby penetrating the manifold 17. The gas supply tubes are provided side by side along a circumferential direction of the inner tube 11. The gas supply tubes are formed at the same height.

At sites of the hydrogen fluoride supply tube 31a that are positioned in the inner tube 11, a plurality of hydrogen fluoride discharge ports 31f are provided. At sites of the ammonia supply tube 32a that are positioned in the inner tube 11, a plurality of ammonia discharge ports 32f are provided.

The discharge ports (the hydrogen fluoride discharge ports 31f and the ammonia discharge ports 32f) are formed at predetermined intervals along extending directions of the gas supply tubes. Each of the discharge ports releases the gas in a horizontal direction. The intervals between the discharge ports are set, for example, to the same intervals as the intervals between the substrates W retained in the boat 16. The positions of the discharge ports in a height direction are set to the middle positions between the substrates W that are next to each other in the up-and-down direction. Thereby, each of the discharge ports can efficiently supply the gas to between the substrates W that are next to each other in the up-and-down direction.

The gas supply 30 may discharge a gas mixture of two or more gases from a single gas supply tube. The gas supply tubes (the hydrogen fluoride supply tube 31a and the ammonia supply tube 32a) may be different from each other in shape and arrangement. Also, the substrate-processing apparatus 1 may further include a gas supply tube for supplying another gas, in addition to the hydrogen fluoride gas and the ammonia gas.

The exhauster 40 is configured to exhaust a gas that is exhausted through the opening 15 from the interior of the inner tube 11 and exhausted from a gas outlet 41 through a space P1 between the inner tube 11 and the outer tube 12. The gas outlet 41 is formed in the side wall of the upper portion of the manifold 17 and above the support 20. An exhaustion path 42 is connected to the gas outlet 41. The exhaustion path 42 sequentially includes a pressure adjusting valve 43 and a vacuum pump 44 with a gap therebetween, and can exhaust the gas in the process chamber 10.

The heater 50 is provided around the outer tube 12. The heater 50 is provided, for example, over a base plate 28. The heater 50 has such a cylindrical shape as to cover the outer tube 12. The heater 50 includes, for example, a heat generator, and is configured to heat the substrates W in the process chamber 10.

The controller 80 is configured to control the operations of the components of the substrate-processing apparatus 1. The controller 80 may be, for example, a computer. Programs for causing the computer to execute the operations of the components of the substrate-processing apparatus 1 are stored in a storage medium 90. The storage medium 90 may be, for example, a flexible disk, a compact disk, a hard disk, a flash memory, or a digital versatile disk (DVD).

### [Operations of Substrate-Processing Apparatus]

Operations in performing the substrate-processing method according to an embodiment by the substrate-processing apparatus 1 will be described.

First, the controller 80 controls the raising and lowering mechanism 25 to: transfer the boat 16, retaining a plurality of substrates W, into the process chamber 10; and hermetically seal the opening at the bottom end of the process chamber 10 with the cover 21 for hermetical closing. Subsequently, the controller 80 controls the exhauster 40 to reduce the internal pressure of the process chamber 10, and controls the heater 50 to adjust the temperature of the substrates W to a predetermined temperature. Each of the substrates W may be the substrate 100 as described above.

Subsequently, the controller 80 controls the gas supply 30, the exhauster 40, and the heater 50 so as to perform HF supply step S20. Specifically, first, the controller 80 controls the heater 50 to maintain the temperature of the substrates W at the first process temperature, and in this state controls the gas supply 30 to supply the first gas into the process chamber 10 and controls the exhauster 40 to maintain the internal pressure of the process chamber 10 at a process pressure. The first gas is a gas that contains the hydrogen fluoride gas and contains no basic gas. Thereby, the silicon oxide film 103 reacts with the hydrogen fluoride gas, thereby forming silicon tetrafluoride.

Subsequently, the controller 80 controls the gas supply 30, the exhauster 40, and the heater 50 so as to perform COR step S30. Specifically, first, the controller 80 controls the heater 50 to adjust the temperature of the substrates W to the second process temperature and maintain the temperature of the substrate W at the second process temperature, and in this state controls the gas supply 30 to supply the second gas into the process chamber 10 and controls the exhauster 40 to maintain the internal pressure of the process chamber 10 at a process pressure. The second gas is a gas that contains both the hydrogen fluoride gas and the basic gas. Thereby, ammonium silicofluoride is formed through reaction of the silicon oxide film 103 with the hydrogen fluoride gas and the basic gas.

Subsequently, the controller 80 increases the internal pressure of the process chamber 10 to the atmospheric pressure and lowers the internal temperature of the process chamber 10 to a dischargeable temperature, and then controls the raising and lowering mechanism 25 to discharge the boat 16 from the process chamber 10.

### EXAMPLES

### Example 1

In Example 1, a wafer including a silicon oxide film and a silicon nitride film on a surface thereof was provided. Subsequently, the provided wafer was housed in the process chamber 10 of the above-described substrate-processing apparatus 1, and HF supply step S20, COR step S30, and PHT step S40 as described above were performed in this order. Subsequently, the etching depths of the silicon oxide film and the silicon nitride film were measured. Conditions of HF supply step S20, COR step S30, and PHT step S40 are as follows.

### (HF Supply Step S20)

Wafer temperature: 65° C.
Process pressure: 0.2 Torr (26.7 Pa)
First gas: HF gas/N₂ gas=300 sccm/2,100 sccm
Duration of process: 20 minutes

### (COR Step S30)

Wafer temperature: 65° C.
Process pressure: 0.2 Torr (26.7 Pa)
Second gas: HF gas/NH₃ gas/N₂ gas=300 sccm/300 sccm/1, 800 sccm
Duration of process: 60 seconds

### (PHT Step S40)

Wafer temperature: 200° C.
Third gas: H₂ gas
Duration of process: 30 minutes

### Comparative Example 1

In Comparative example 1, similar to Example 1, a wafer including a silicon oxide film and a silicon nitride film on a surface thereof was provided. Subsequently, the provided wafer was housed in the process chamber 10 of the substrate-processing apparatus 1, and COR step S30 and PHT step S40 were performed in this order without performing HF supply step S20 as described above. Subsequently, similar to Example 1, the etching depths of the silicon oxide film and the silicon nitride film were measured. Conditions of COR step S30 and PHT step S40 are the same as those of COR step S30 and PHT step S40 in Example 1.

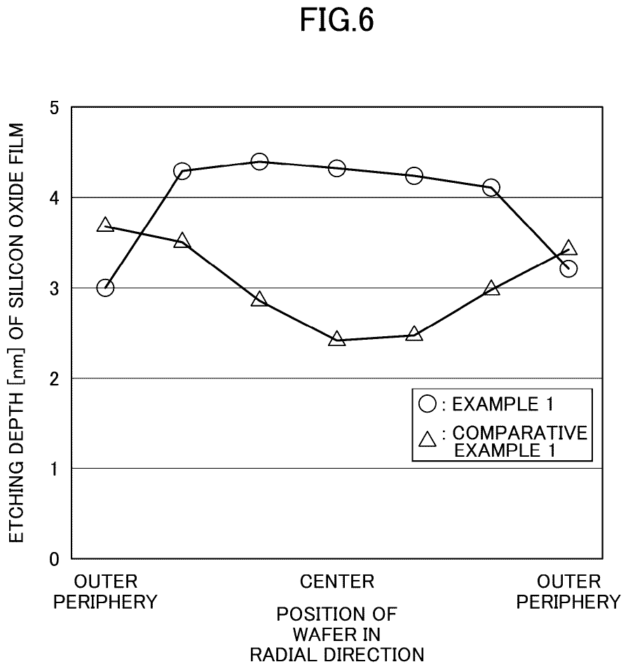

FIG. 6 is a graph indicating the results obtained by measuring the in-plane distribution of the etching depth of the silicon oxide film. In FIG. 6, the horizontal axis indicates the position of the wafer in a radial direction, and the vertical axis indicates the etching depth [nm] of the silicon oxide film. In FIG. 6, a circular mark indicates the result of Example 1, and a triangular mark indicates the result of Comparative Example 1.

As indicated by the circular mark in FIG. 6, in Example 1, the etching depth of the silicon oxide film is larger at the center of the wafer than the etching depth of the silicon oxide film at the outer periphery of the wafer. In other words, in Example 1, the resulting in-plane profile of the etching depth of the silicon oxide film is convex.

Meanwhile, as indicated by the triangular mark in FIG. 6, in Comparative Example 1, the etching depth of the silicon oxide film at the center of the wafer is smaller than the etching depth of the silicon oxide film at the outer periphery of the wafer. In other words, in Comparative Example 1, the resulting in-plane profile of the etching depth of the silicon oxide film is concave. This result demonstrates that by performing HF supply step S20 before COR step S30, the in-plane profile of the etching depth of the silicon oxide film is adjustable from the concave profile to the convex profile.

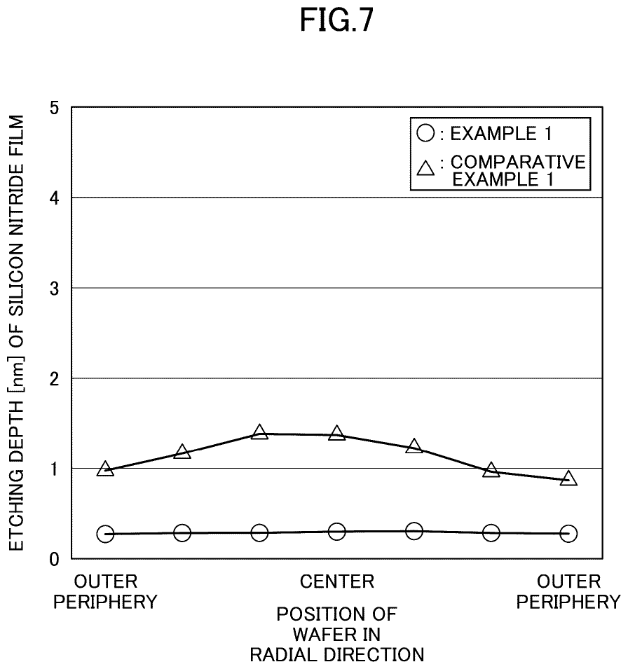

FIG. 7 is a graph indicating the results obtained by measuring the in-plane distribution of the etching depth of the silicon nitride film. In FIG. 7, the horizontal axis indicates the position of the wafer in a radial direction, and the vertical axis indicates the etching depth [nm] of the silicon nitride film. In FIG. 7, a circular mark indicates the result of Example 1, and a triangular mark indicates the result of Comparative Example 1.

As indicated in FIG. 7, in Comparative Example 1, the etching depth of the silicon nitride film is about 1 nm (nanometer) while in Example 1, the etching depth of the silicon nitride film is about 0.2 nm. This result demonstrates that by performing HF supply step S20 before COR step S30, the etching depth of the silicon nitride film can be reduced. That is, this demonstrates being able to enhance etching selectivity of the silicon oxide film relative to the silicon nitride film.

From the experiments that were conducted by the present inventors, it is found that as the native oxide film on the silicon nitride film becomes thicker, the etching depth of the silicon nitride film achieved in COR step S30 is increased. From this, conceivably, the native oxide film on the silicon nitride film was etched in HF supply step S20 and the native oxide film did not significantly exist on the silicon nitride film at the time of COR step S30, and thus etching of the silicon nitride film was suppressed.

According to the present disclosure, the in-plane distribution of the etching depth can be adjusted.

It should be understood that the embodiments disclosed herein are illustrative and not restrictive in all respects. Various omissions, substitutions, and changes may be made to the above-described embodiments without departing from the scope of claims recited and the spirit of the disclosure.

The above-described embodiments are related to the batch-type substrate-processing apparatus configured to perform the process to the plurality of substrates all at once. However, the present disclosure is not limited to this. For example, the substrate-processing apparatus may be a single substrate-processing apparatus configured to process a plurality of substrates one by one. For example, the substrate-processing apparatus may be a semi-batch-type apparatus configured to perform a process to a plurality of substrates by rotating the substrates on a rotation table in a process chamber so as to sequentially pass through a plurality of processing regions that are disposed along a rotating direction of the rotation table.

What is claimed is:

1. A substrate-processing method, comprising:
(a) providing a substrate including a silicon oxide film on a surface of the substrate;
(b) supplying a first gas to the surface of the substrate, the first gas containing a hydrogen fluoride gas and containing no basic gas; and
(c) after (b), supplying a second gas to the surface of the substrate, the second gas containing both a hydrogen fluoride gas and a basic gas.

2. The substrate-processing method according to claim 1, wherein
(c) is performed successively after (b) in a state in which supply of the hydrogen fluoride gas is continued.

3. The substrate-processing method according to claim 1, wherein
a duration of (b) is longer than a duration of (c).

4. The substrate-processing method according to claim 1, wherein
(b) includes reacting the silicon oxide film and the hydrogen fluoride gas, thereby forming silicon tetrafluoride, and
(c) includes reacting the silicon tetrafluoride, the hydrogen fluoride gas, and the basic gas, thereby forming ammonium silicofluoride.

5. The substrate-processing method according to claim 1, wherein
in (b) and (c), the substrate is maintained at the same temperature.

6. The substrate-processing method according to claim 1, wherein
in (c), the second gas is supplied along the surface of the substrate.

7. The substrate-processing method according to claim 1, wherein
(c) includes etching the silicon oxide film such that an etching depth of the silicon oxide film at a center of the substrate is larger than an etching depth of the silicon oxide film at an outer periphery of the substrate.

8. The substrate-processing method according to claim 1, wherein
the basic gas is an ammonia gas.

9. The substrate-processing method according to claim 1, further comprising:
(d) after (c), heat-treating the substrate at a temperature that is higher than in (c).

10. The substrate-processing method according to claim 2, further comprising:
(d) after (c), heat-treating the substrate at a temperature that is higher than in (c).

11. The substrate-processing method according to claim 3, further comprising:
(d) after (c), heat-treating the substrate at a temperature that is higher than in (c).

12. The substrate-processing method according to claim 4, further comprising:
(d) after (c), heat-treating the substrate at a temperature that is higher than in (c).

13. The substrate-processing method according to claim 5, further comprising:
(d) after (c), heat-treating the substrate at a temperature that is higher than in (c).

14. The substrate-processing method according to claim 6, further comprising:
(d) after (c), heat-treating the substrate at a temperature that is higher than in (c).

15. The substrate-processing method according to claim 7, further comprising:
(d) after (c), heat-treating the substrate at a temperature that is higher than in (c).

16. The substrate-processing method according to claim 8, further comprising:
(d) after (c), heat-treating the substrate at a temperature that is higher than in (c).

17. A substrate-processing apparatus, comprising:
a process chamber configured to house a substrate;
a gas supply configured to supply a process gas into the process chamber; and
a controller, wherein
the controller includes a processor and a memory storing one or more programs, which when executed, cause the processor to execute a process including:
(a) housing a substrate in the process chamber, the substrate including a silicon oxide film on a surface of the substrate;
(b) supplying a first gas to the surface of the substrate housed in the process chamber, the first gas containing a hydrogen fluoride gas and containing no basic gas; and
(c) after (b), supplying a second gas to the surface of the substrate housed in the process chamber, the second gas containing both a hydrogen fluoride gas and a basic gas.
